(19) United States
(12) Patent Application Publication
(10) Pub. No.: US 2026/0165084 A1
(43) Pub. Date: Jun. 11, 2026

(54) ELECTRIC FIELD INDUCED STRAIN IN PIEZOELECTRIC MATERIAL FOR CARRIER WAFER SEPARATION

(71) Applicant: Micron Technology, Inc., Boise, ID (US)

(72) Inventors: Srinivasa Reddy Yeduru, Meridian, ID (US); Farrell M. Good, Meridian, ID (US); Matthew Thorum, Boise, ID (US); Gurtej S. Sandhu, Boise, ID (US)

(21) Appl. No.: 19/362,238

(22) Filed: Oct. 17, 2025

Related U.S. Application Data
(60) Provisional application No. 63/729,951, filed on Dec. 9, 2024.

(51) Int. Cl. H01L 21/683

(52) U.S. Cl. CPC H10P 72/74; H10P 72/7412; H10P 72/744

(57) ABSTRACT

A semiconductor device manufacturing system is introduced. The system includes a carrier wafer, a first electrode layer disposed on the carrier wafer, a piezoelectric layer disposed on the first electrode layer, and a second electrode layer disposed on the piezoelectric layer. In addition, the system includes a device wafer having a bonding layer disposed on a surface of the device wafer, and a power source having a first terminal and a second terminal. The device wafer is bonded to the carrier wafer through the bonding layer, the first electrode layer, the piezoelectric layer, and the second electrode layer. The second electrode layer is configured to separate from the first electrode layer upon application of a bias voltage to the first and second electrode layers, and the device wafer is configured to debond from the carrier wafer through delaminating the piezoelectric layer from the first or second electrode layer.

### CROSS-REFERENCE TO RELATED APPLICATION(S)

The present application claims priority to U.S. Provisional Patent Application No. 63/729,951, filed Dec. 9, 2024, the disclosure of which is incorporated herein by reference in its entirety.

### TECHNICAL FIELD

The present disclosure generally relates to semiconductor device assemblies, and more particularly relates to electric field induced strain in piezoelectric material for carrier wafer separation.

### BACKGROUND

Semiconductor packages typically include a semiconductor die or a semiconductor wafer (e.g., memory chip, microprocessor chip, imaging chip) mounted on a substrate or an interface wafer and encased in a protective covering (e.g., an encapsulating material). The semiconductor die or semiconductor wafer may include functional features, such as memory cells, processor circuits, or imaging devices, as well as bond pads electrically connected to the functional features. The process of attaching semiconductor dice on a semiconductor wafer in general refers as chips on wafer (CoW) process, which can increase throughput and reduce difficulties in handling individual semiconductor dice as they continue to shrink in size. Individual semiconductor dice can further be stacked in the semiconductor assemblies. Further, bonding technologies such as adhesive bonding, direct bonding, or thermocompression bonding processes can be adopted for attaching a semiconductor wafer to a carrier wafer.

In advanced semiconductor manufacturing, the carrier wafer is often utilized to provide structural support to semiconductor dice. Particularly, this carrier wafer can be essential when handling very thin or fragile semiconductor dice that could be damaged during the packaging process. For example, semiconductor dice or semiconductor wafer can be temporarily bonded to the carrier wafer to allow for easier processing through various packaging steps, and later de-bonded or released from the carrier wafer. Various techniques such as laser de-bonding process or plasma debonding process can be adopted for de-bonding semiconductor wafers from the carrier wafer. The choice of de-bonding technique depends on the thermal sensitivity of the dice, the carrier material, and the tolerance for mechanical stress. It requires a balance between effectively releasing the semiconductor die from the carrier wafer and ensuring that the semiconductor die or semiconductor wafer is not damaged in the process. As semiconductor technology advances and semiconductor dice become thinner and more fragile, the development of innovative de-bonding techniques is desired.

### BRIEF DESCRIPTION OF THE DRAWINGS

FIG. 1 is a schematic diagram of a semiconductor device manufacturing system in accordance with one or more embodiments of the present technology.

FIG. 2 is a partially schematic diagram of a semiconductor device manufacturing system configured in accordance with one or more embodiments of the present technology.

FIG. 3 is a partially schematic diagram of another semiconductor device manufacturing system configured in accordance with one or more embodiments of the present technology.

FIG. 4 is a partially schematic diagram of another semiconductor device manufacturing system configured in accordance with one or more embodiments of the present technology.

FIG. 5 is a partially schematic diagram of another semiconductor device manufacturing system configured in accordance with one or more embodiments of the present technology.

FIG. 6 shows a hysteresis characteristic curve of a piezoelectric material in accordance with one or more embodiments of the present technology.

FIGS. 7A and 7B are enlarged, partially schematic diagram of a piezoelectric layer configured in accordance with one or more embodiments of the present technology.

FIG. 8 is an enlarged, partially schematic diagram of a semiconductor device manufacturing system after debonding and configured in accordance with one or more embodiments of the present technology.

FIG. 9 is a flowchart illustrating a method for manufacturing a semiconductor device in accordance with one or more embodiments of the present technology.

FIG. 10 is a schematic block diagram of a system that includes a semiconductor device assembly configured in accordance with one or more embodiments of the present technology.

### DETAILED DESCRIPTION

The semiconductor wafer debonding process is a critical step in the fabrication of advanced devices. It separates the device wafer from the carrier wafer after various fabrication steps, enabling the production of thin and flexible semiconductor devices. These devices are increasingly in demand for applications such as flexible electronics, advanced packaging, high-capacity memory devices, and three-dimensional integrated circuits (3D ICs). In advanced packaging technologies like wafer-level packaging (WLP) and fan-out wafer-level packaging (FOWLP), debonding is used to handle thin wafers essential for creating compact, high-performance packages. In 3D ICs, where multiple layers of devices are stacked vertically, thin wafers are required, and debonding ensures their safe handling without damage.

A primary challenge in the debonding process is selecting an adhesive that can securely bond the device wafer to the carrier wafer during processing, yet be easily removed without causing damage, e.g., on the device wafer or the carrier wafer. The adhesive must endure high temperatures and chemical exposure. Mechanical stress introduced during debonding can also lead to wafer breakage or damage, so the process must be gentle to maintain wafer integrity.

In semiconductor device manufacturing, particularly with thin wafer processing, backside processing, advanced interconnects, and 3D integration, carrier wafers provide mechanical support and stability to delicate device wafers during various steps like wafer thinning or backside processing. After these steps, the carrier wafers are typically destroyed while still bonded to the device wafers, allowing further packaging. However, destroying carrier wafers requires new ones for further processing of each incoming device wafer, leading to significant material and process costs.

To solve the issues and challenges described above, the present technology introduces an innovative semiconductor device assembly process by implementing piezoelectric material between a device wafer and a carrier, forming strain and strain induced defects in the piezoelectric material in assisting device wafer debonding from the carrier wafer. In particular, the present technology forms a metal-insulator-metal (MIM) stack including an upper electrode layer, a piezoelectric layer, and a lower electrode layer on the carrier wafer. By applying a bias voltage from a voltage source to the upper and lower electrode layers, the present technology generates strain in the piezoelectric layer. Piezoelectric materials are a class of smart materials that exhibit a piezoelectric effect, where they generate a mechanical strain in response to an electric charge. In the present technology, the piezoelectric layer of the MIM stack undergoes large deformations caused by the mechanical strain and forms defects therein. Specifically, the defects of the piezoelectric layer are formed along an interface between the piezoelectric layer and the upper or lower electrode, which assist the device wafer debonding process. Alternatively, shape memory materials can be utilized in the present technology to generate strain at the wafer interface in assisting the wafer debonding process.

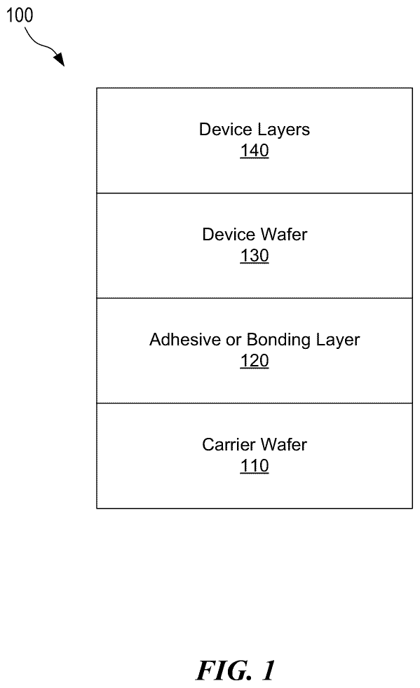

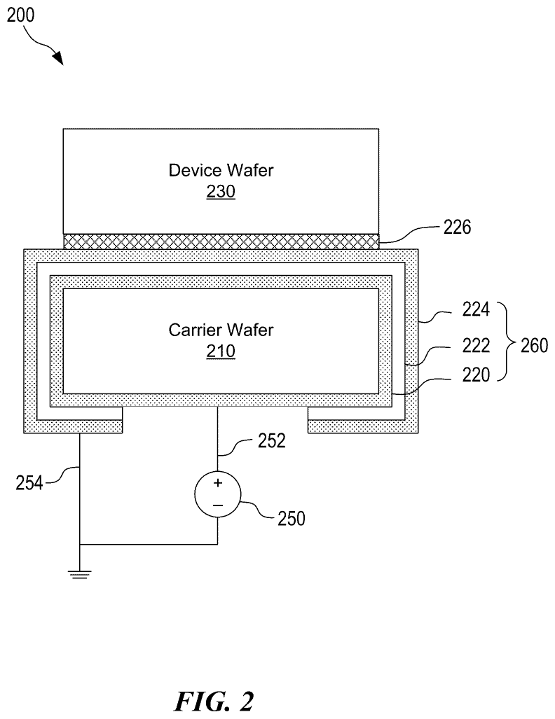

FIG. 1 is a partially schematic diagram of a semiconductor device manufacturing system 100 (“the system 100”). The system 100 includes a carrier wafer 110 and a device wafer 130 bonded to the carrier wafer 110 via an adhesive or bonding layer 120. When manufacturing a semiconductor device, the carrier wafer 110 (e.g., a silicon wafer) can provide mechanical support and stability to the device wafer 130 as the device wafer 130 is subjected to various processing. For example, in some embodiments, the device wafer 130 undergoes various wafer processing steps including thinning, backside processing, patterning and etching, implantation and doping, and/or the like. In some embodiments, one or more device layers 140 are formed (e.g., deposited) on the side of the device wafer 130 opposite the carrier wafer 110. Once the processing of the device wafer 130 and/or formation of the one or more device layers 140 are completed, the carrier wafer 110 is destructively removed via back-grinding, etching, and/or the like. However, the sacrificial nature of the carrier wafer 110 requires a new carrier wafer to be used and destroyed for each device wafer. The material and process costs associated with using a new carrier wafer can be significant (e.g., about $80 per wafer). To address these problems and others, embodiments of the present technology provide a way to reuse carrier wafers, as illustrated in and discussed below with reference to FIGS. 2-9. Specifically, piezoelectric materials can be adopted into the semiconductor device manufacturing system 100, e.g., as a portion of or disposed close to the adhesive or bonding layer 120, to debond the device wafer 130 from the carrier wafer 110.

FIG. 2 is a partially schematic diagram of a semiconductor device manufacturing system 200 (“the system 200”) configured in accordance with embodiments of the present technology. The system 200 includes a carrier wafer 210, a MIM stack 260 deposited on the carrier wafer 210, and a device wafer 230 bonded to the MIM stack 260. The carrier wafer 210 and/or the device wafer 230 can each comprise a silicon wafer. In addition, the MIM stack 260 can be disposed between the carrier wafer 210 and the device wafer 230, and can include a plurality of layers, as shown.

In some embodiments, the MIM stack 260 includes a first electrode layer 220, a second electrode layer 224, and a piezoelectric layer 222. The first electrode layer 220 (also referred to as the bottom electrode layer) is disposed on and wraps around all surfaces the carrier wafer 210. As shown in FIG. 2, the first electrode layer 220 is disposed on the frontside surface, backside surface and side surfaces of the carrier wafer 210. The piezoelectric layer 222 is disposed on the first electrode layer 220, surrounding all surfaces of the carrier wafer 210. In the present technology, the first electrode layer 220 comprises tungsten (W), titanium nitride (TiN), titanium (Ti), and/or other suitable material. The second electrode layer 224 (also referred to as the top electrode layer) is disposed on the piezoelectric layer 222. Specifically, the second electrode layer 224 is disposed on the frontside surface, the edge surfaces, and at least a portion of the backside surface of the carrier wafer 210. As shown in FIG. 2, the second electrode layer 224 is sandwiched between the device wafer 230 and the piezoelectric layer 222, above the frontside surface of the carrier wafer 210. The second electrode layer 224 comprises tungsten (W), ruthenium (Ru), carbon (C), and/or other suitable material. The first and second electrode layers 220 and 224 can be made of a same type of conductive material. In some other examples, the first and second electrode layers 220 and 224 can be made of various types of conductive materials.

In some embodiments, the system 200 also includes a bonding layer 226 that is disposed between the device wafer 230 and the carrier wafer 210. In particularly, the bonding layer 226 can be disposed between the device wafer 230 and the second electrode layer 226. Here, the bonding layer 226 is configured to bond the device wafer 230 with the MIM stack 260 of the carrier wafer 210. The bonding layer 226 comprises dielectric materials such as silicon dioxide and silicon nitride, polymers such as polyimide, conductive metals such as gold, copper, and Tin, organic-inorganic hybrid materials, and solder materials such as indium and lead-tin alloys. As shown in FIG. 2, the piezoelectric layer 222 is disposed between the first electrode layer 220 and the second electrode layer 224. The piezoelectric layer 222 comprises Lead Zirconate Titanate (Pb(Zr,Ti)O₃), Lead Zinc Niobate (Pb(Zn,Nb)O₃), Lead Titanate (PbTiO₃), Barium Titanate (BaTiO₃), and/or other suitable materials. Each of the layers 220, 222, and 224 of the MIM stack 260 can be deposited (or otherwise formed) on the carrier wafer 210 via atomic layer deposition (ALD) and/or other suitable methods. The MIM stack 260 can be deposited to cover an entirety or only a portion of the carrier wafer 210. In some other embodiments, the MIM stack 260 can be bonded to the carrier wafer 210 and/or the device wafer 230 via dielectric-dielectric bonding. It is appreciated that the components illustrated in FIG. 2 are not drawn to scale. For example, the thickness of each of the carrier wafer 210 and the device wafer 230 can be on the scale of microns (μm) while the thickness of each of the layers 220, 222, and 224 of the MIM stack 260 can be on the scale of nanometers (nm). Specifically, the piezoelectric layer 222 may have a thickness ranging from 1 nm to 1 μm.

In some embodiments, the second electrode layer 224 and the piezoelectric layer 222 can be partially patterned on the backside surface of the carrier wafer 210, exposing a portion of the first electrode layer 220. In addition, a voltage source 250 is electrically coupled to the MIM stack 260 on the back side of the carrier wafer 210 (opposite the device wafer 230). As shown in FIG. 2, portions of the MIM stack 260 on the back side of the carrier wafer 210 are removed to expose the first electrode layer 220, allowing a first lead 252 extending from the positive terminal of the voltage source 250 to couple to the first electrode layer 220 and a second lead 254 extending from the negative terminal of the voltage source 250 to couple to the second electrode layer 224. The second lead 254 can also be coupled to the ground. In other embodiments, the first lead 252 and/or the second lead 254 can be coupled to the second electrode layer 224 and the first electrode layer 220, respectively, without removing portions of the MIM stack 260. For example, the first lead 252 and/or the second lead 254 can have an insulating sleeve and be inserted directly into the MIM stack 260.

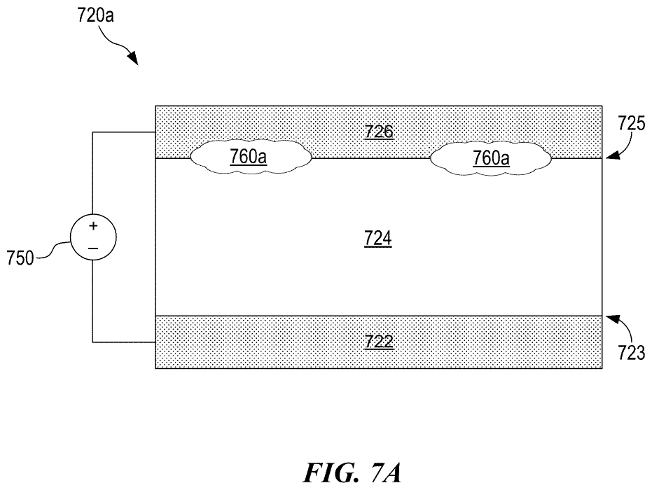

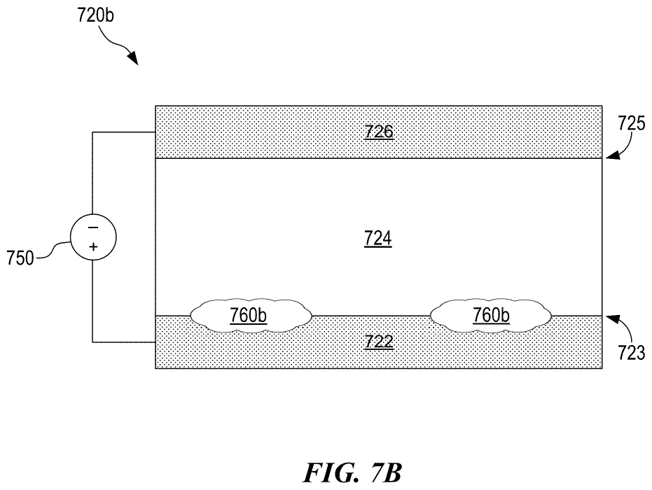

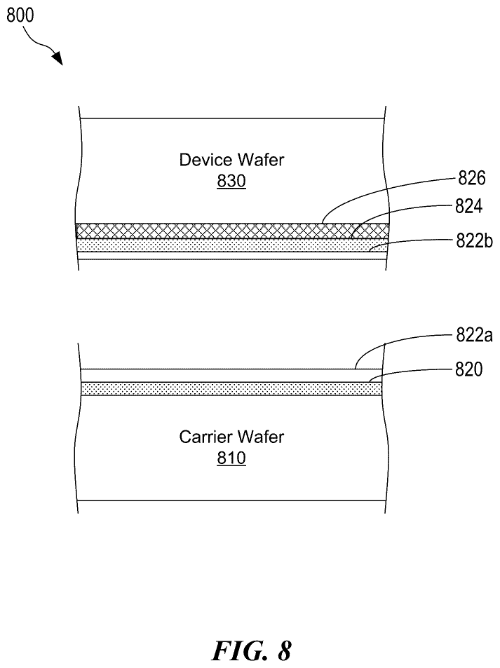

As discussed in further detail below with reference to FIGS. 7A, 7B and 8, the voltage source 250 can be operated to apply a bias voltage to the first electrode layer 220 and the second electrode layer 224. Application of the bias voltage can cause the second electrode layer 224 to separate from the piezoelectric layer 222, thereby separating the device wafer 230 from the carrier wafer 210. In some embodiments, the voltage source 250 is electrically coupled to the MIM stack 260 only once the system 200 is ready for this debonding step. Therefore, the device wafer 230, and thus the rest of the semiconductor device manufactured, can be free of the carrier wafer 210 without the need to destructively remove the carrier wafer 210. By preserving the carrier wafer 210 during the debonding process, the carrier wafer 210 can be reused in the manufacture of additional semiconductor devices. This can directly result in material, process, and associated cost savings.

In the present technology, after bonding the device wafer 230 to the MIM stack 260 of the carrier wafer 210, various semiconductor fabrication processes can be adopted to process the device wafer 230. Here, the processing the device wafer comprises fabricating one or more memory devices or one or more Complementary Metal-Oxide-Semiconductor (CMOS) devices, and wherein the one or more memory devices comprises dynamic random access memory (DRAM) devices or NAND flash memory devices.

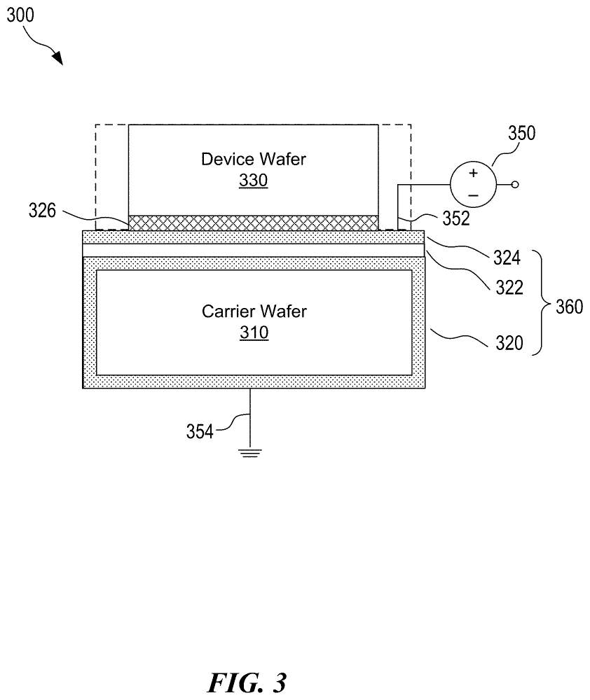

FIG. 3 is a partially schematic diagram of another semiconductor device manufacturing system 300 (“the system 300”) configured in accordance with one or more embodiments of the present technology. The system 300 includes a carrier wafer 310, a MIM stack 360 deposited on the carrier wafer 310, and a device wafer 330 bonded to the MIM stack 360. The carrier wafer 310 and/or the device wafer 330 can each comprise a silicon wafer. In this example, the MIM stack 360 can be disposed between the carrier wafer 310 and the device wafer 330, and can include a plurality of layers. For example, the MIM stack 360 includes a first electrode layer 320, a second electrode layer 324, and a piezoelectric layer 322 disposed between the first and second electrode layers 320 and 324. As shown, the first electrode layer 320 (also referred to as the bottom electrode layer) is disposed on and wraps around all surfaces the carrier wafer 310. For example, the first electrode layer 320 is disposed on the frontside surface, backside surface and side surfaces of the carrier wafer 310. The piezoelectric layer 322 is disposed on the first electrode layer 320 and above the frontside surface of the carrier wafer 210. The second electrode layer 324 is disposed on the piezoelectric layer 322 and above the frontside surface of the carrier wafer 210. The system 300 also includes a bonding layer 326 disposed between the device wafer 330 and the second electrode layer 324. In this example, the material composition and fabrication technologies for processing layers 320, 322, 324, and 326 can be similar to that of the layers 220, 222, 224, and 226 disclosed in the system 200 of FIG. 2. In this example, the piezoelectric layer 322 has a thickness ranging from 1 nm to 1 μm.

In this example, the device wafer 330 as well as the bonding layer 326 can be trimmed or etched at the wafer edge, exposing an edge region of the second electrode layer 324. Various semiconductor process technologies can be adopted here to trim the device wafer 330, such as laser cutting and etching, plasma etching, wet chemical etching, and drying etching technologies. Specifically, a semiconductor patterning process can be implemented to trim the device wafer 330 on its edge.

In the system 300, a voltage source 350 can be operated to apply a bias voltage to the first electrode layer 320 and the second electrode layer 324. The voltage source 350 is electrically coupled to the MIM stack 360 on the back side and frontside of the carrier wafer 210. As shown in FIG. 3, a first lead 352 extending from the positive terminal of the voltage source 350 is coupled to the exposed region of the second electrode layer 324. In addition, a second lead 354 extending from the negative terminal of the voltage source 350 is coupled to the first electrode layer 220. In some other examples, the second lead 354 can be connected to the ground. In other embodiments, the first lead 352 and/or the second lead 354 can be coupled to the first electrode layer 320 and the second electrode layer 324, respectively. For example, the first lead 352 can have an insulating sleeve and be inserted directly into the MIM stack 360. In this example, a bias voltage can be applied on the piezoelectric layer 322 to form strain and defects therein, which assists the delamination of device wafer 330 from the carrier wafer 310 in downstream wafer debonding processes.

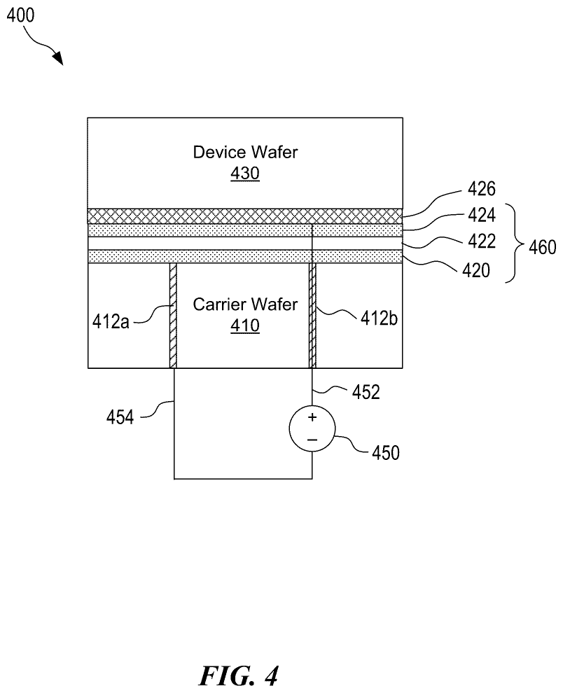

FIG. 4 is a partially schematic diagram of another semiconductor device manufacturing system 400 (“the system 400”) configured in accordance with one or more embodiments of the present technology. The system 400 includes a carrier wafer 410, a MIM stack 460 deposited on the carrier wafer 410, and a device wafer 430 bonded to the MIM stack 460. The carrier wafer 410 and/or the device wafer 430 can each comprise a silicon wafer. In this example, the MIM stack 460 can be disposed between the carrier wafer 410 and the device wafer 430, and can include a plurality of layers. As shown, the MIM stack 460 includes a first electrode layer 420, a second electrode layer 424, and a piezoelectric layer 422 disposed between the first and second electrode layers 420 and 424. Here, the first electrode layer 420 (also referred to as the bottom electrode layer) is disposed on the frontside surface of the carrier wafer 410. Further, the piezoelectric layer 422 is disposed on the first electrode layer 420. Additionally, the second electrode layer 424 is disposed on the piezoelectric layer 422 and above the frontside surface of the carrier wafer 310. The system 400 also includes a bonding layer 426 disposed between the device wafer 430 and the second electrode layer 424. In this example, the material composition and fabrication technologies for layers 420, 422, 424, and 426 can be similar to that of the layers 220, 222, 224, and 226 disclosed in the system 200 of FIG. 4.

Unlike the systems 200 and 300, the system 400 further includes a first through-silicon via (TSV) 412a and a second TSV 412b each extending through the carrier wafer 410. Specifically, the first and second TSVs 412a and 412b extend from a backside surface to a frontside surface of the carrier wafer 410. Here, the first lead 452 is electrically coupled to the second electrode layer 424 through or via the second TSV 412b, and the second lead 454 is electrically coupled to the first electrode layer 420 through or via the first TSV 412a. In some embodiments, the portions of the leads extending through the layers of the MIM stack 460 are insulated. Therefore, by including one or more TSVs, the system 400 avoids the need to remove portions of the MIM stack to expose certain layers thereof. As discussed in further detail below with reference to FIGS. 7A, 7B and 8, the voltage source 350 can be operated to apply a bias voltage to the first electrode layer 420 and the second electrode layer 424. The bias voltage applied can cause the second electrode layer 424 to separate from the piezoelectric layer 422, thereby separating the device wafer 430 from the carrier wafer 410 in downstream wafer debonding processes.

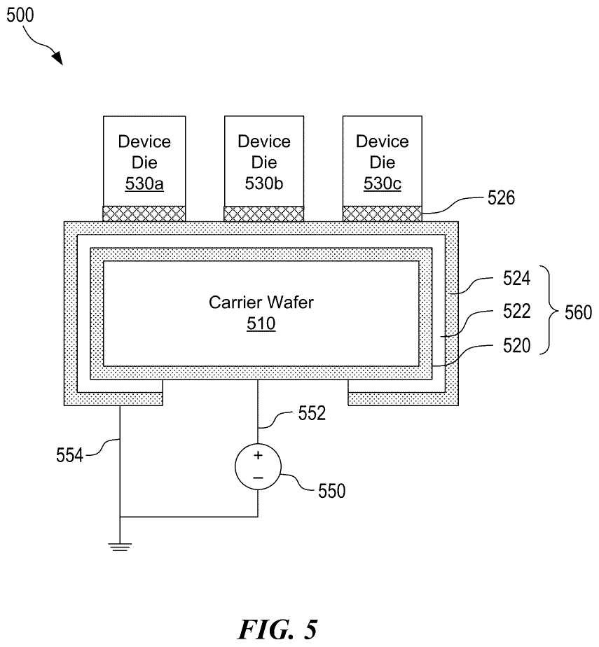

FIG. 5 is a partially schematic diagram of another semiconductor device manufacturing system 500 (“the system 500”) configured in accordance with one or more embodiments of the present technology. The system 500 relates to packaging of semiconductor chiplet for advanced semiconductor devices. Specifically, individual semiconductor dice (chips) can be bonded on a carrier wafer for further process or integration into larger systems. The system 500 can be implemented for creating of multi-chip modules, 3D integrated circuits, and other complex semiconductor structures. As shown in FIG. 5, individual device dice 530a, 530b, and 530c can be bonded on a carrier wafer 510. Each one of the individual device dice 530a, 530b, and 530c can be diced from semiconductor wafers using techniques such as laser cutting or mechanical sawing. In this example, the system 500 includes the carrier wafer 510 and a MIM stack 560 similar to the carrier wafer 210 and MIM stack 260 described in FIG. 2. Similarly, the MIM stack 560 includes a first electrode layer 520, a second electrode layer 524 and a piezoelectric layer 522 disposed between the first and second electrode layers 520 and 524. As shown, the first electrode layer 520 wraps around the carrier wafer 510. In addition, the piezoelectric layer 522 and the second electrode layer 524 are disposed on the frontside surface, edge surface, and a portion of the bottom surface of the carrier wafer 510. In this example, a voltage source 550 is connected to the MIM stack 560 on the backside surface of the carrier wafer 510. Specifically, a first lead 552 extending from the positive terminal of the voltage source 550 is coupled to the first electrode layer 520 and a second lead 554 extending from the negative terminal of the voltage source 550 is coupled to the second electrode layer 524.

As shown in FIG. 5, each one of the device dice 530a, 530b, and 530c can be bonded on the carrier wafer 510, through the corresponding bonding layer 526. The bonding layer 526 can be made of materials similar to the bonding layer 226 disclosed in FIG. 2. Specifically, the device dice 530a, 530b, and 530c are bonded to the second electrode layer 524. Various semiconductor bonding technologies such as thermocompression bonding, fusion bonding, or hybrid bonding can be adopted to bond the device dice to the MIM stack 560 of the carrier wafer 510. In this example, a bias voltage can be applied, from the voltage source 550 and through the first lead 552 and the second lead 554, to the MIM stack 560 specifically the piezoelectric layer 522. The applied external electric field (E-field) could induce strain in the piezoelectric layer 522 and further cause defects, e.g., close to the upper interface between the second electrode layer 524 and the piezoelectric layer 522 and the lower interface between the first electrode layer 520 and the piezoelectric layer 522. The induced strain and defects in the piezoelectric layer 522 assist in the delamination of device dice 530a, 530b, and 530c from the carrier wafer 510 in downstream processes.

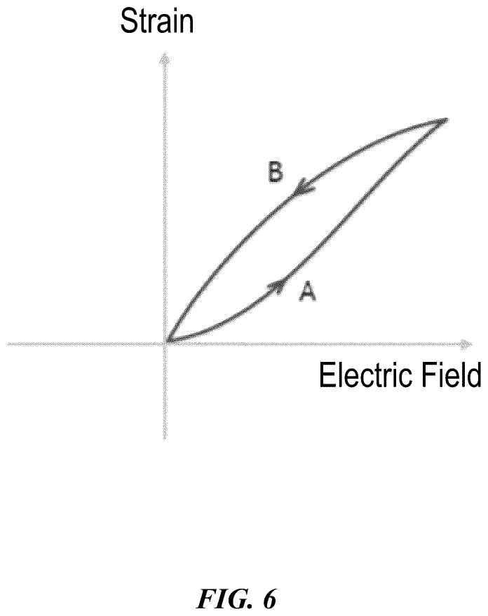

Piezoelectric materials are unique in their ability to convert mechanical energy into electrical energy and vice versa. This property can be due to the alignment of electric dipoles within the material, which can be influenced by an E-field. When an E-field is applied, it induces a mechanical strain in the material, leading to material deformation. This phenomenon is known as the piezoelectric effect. FIG. 6 discloses a hysteresis characteristic curve of a piezoelectric material that can be adopted in one or more embodiments of the present technology for carrier wafer debonding. As shown in the curve portion A, when an external E-field is applied to a piezoelectric material, the electric dipoles within the material align themselves according to the direction of the E-field. This alignment of these dipoles can generate an internal stress within the piezoelectric material, causing it to deform. This deformation is observed as strain. When the E-field is reducing, the strain comprised in the material decreases as shown in the curve portion B. The relationship between the applied E field and the resulting strain is depicted in the hysteresis loop of FIG. 6. This loop illustrates the non-linear and path-dependent nature of the strain response. As the E-field is cycled, the strain follows a looped path, indicating energy loss due to internal friction and other dissipative processes.

In the present technology, the effectiveness of strain cumulation in piezoelectric materials depends on several factors related to the applied E-field. For example, the magnitude of the E field must be sufficient to align the dipoles within the piezoelectric material. Higher field strengths generally result in greater strain. Additionally, the frequency of the applied E-field can influence the dynamic response of the piezoelectric material. High-frequency E-fields can induce rapid strain changes, which is useful in fastening strain cumulation in the piezoelectric material. Further, the temperature of the piezoelectric material can affect its piezoelectric properties. For instance, some materials may exhibit enhanced piezoelectric effects at certain temperatures. Accordingly, the carrier wafer as well as the semiconductor device manufacturing systems described above can be processed in an elevated temperature, e.g., through a thermal chuck under the carrier wafer during the processing steps. In the present technology, these deformations induced in the piezoelectric materials are particularly significant in ferroelectric materials, a subset of piezoelectric materials known for their high piezoelectric coefficients and strong coupling between electrical and mechanical states.

In one or more embodiments of the present technology, the piezoelectric materials adopted can be cycled many times by tuning the E-field applied to them. This cycling involves repeatedly applying and removing the E-field, causing the material to expand and contract. The repeated cycling and the associated large deformations can lead to mechanical strain at the interfaces between the piezoelectric material and the electrodes (either top or bottom). Over time, the strain can cause the interfaces to degrade, potentially leading to various defects such as cracks, dislocations, vacancies, and delamination. For example, the mechanical strain caused in the piezoelectric material can cause microcracks to form at the film-electrode interface, which can propagate into the piezoelectric material. In addition, the mechanical strain may introduce defects such as edge dislocation, screw dislocations, threading dislocations, grain boundaries, and other defects in the piezoelectric material. Piezoelectric materials have domains, which are regions where the electric dipoles are uniformly aligned. Under mechanical strain, these domains can switch their orientation. This switching is reversible, meaning the domains can return to their original orientation when the strain is removed. This reversible domain switching likely causes point defects in the piezoelectric material. As a result, the chemical bonding between the piezoelectric material and the corresponding electrode can weaken, leading to delamination or separation of the piezoelectric material and the corresponding electrode.

In some other embodiments, the present technology uses shape memory materials to assist the separation of the carrier wafer. Specifically, shape memory materials can induce interface distortion to debond the carrier wafer from the device wafer. Shape memory materials are a class of smart materials capable of converting heat into mechanical strain (or vice versa) through a martensitic phase transformation. For example, a shape memory material can be converted between an austenite phase with a cubic crystal structure and a martensite phase with a monoclinic crystal structure, through applying various thermal treatments. In another example, oligo crystalline structures reduce internal mismatch stresses during the martensitic transformation, leading to robust shape memory ceramics capable of enduring many super elastic cycles with large strains (e.g., up to 7% strain). Further, oxide ceramic materials can be excellent candidates as shape memory materials utilized in the present technology. In the device wafer debonding process, an initial elastic loading of austenite phase can be followed by forward transformation plateaus during the formation of martensite phase. This is subsequently followed by elastic unloading and reverse transformation plateaus, resulting in a reversion to the austenite phase.

For the application of device wafer debonding using shape memory materials, the shape memory materials can be sandwiched between an upper heat-absorbing material layer and a lower sacrificial epitaxial film. The configuration of the device wafer debonding system can be similar to the above described on FIGS. 1-5. For example, the upper heat-absorbing material layer can be positioned between the device wafer (or a device wafer bonding interface layer) and the shape memory material layer. Additionally, the lower sacrificial layer can be placed between the shape memory material layer and the carrier wafer. In this example, the lower sacrificial layer can be configured to grow epitaxial films (e.g., silicon dioxide) that act as a resistive layer for a Joule heating process. During the device wafer debonding process, the device wafer—carrier wafer interface is delaminated/weakened through temperature induced shape memory material deformation therebetween.

In these embodiments, the shape memory materials can be tuned by adjusting the temperature. Several shape memory materials could be potential candidates depending on the temperature budget (e.g., shape memory metals, shape memory oxides, or ceramics). Among these, materials that exhibit high deformations or strains would be ideal for this application. The ability to select and tune the appropriate shape memory material based on the specific temperature requirements ensures optimal performance and efficiency in the wafer debonding process.

In the present technology, the E-field induced strain in the piezoelectric material may exist close to the upper interface between the piezoelectric material and the upper electrode or the lower interface between the piezoelectric material and the lower electrode. For example, FIGS. 7A and 7B shows enlarged, partially schematic diagram of piezoelectric metal-insulator-metal (MIM) stacks configured in accordance with one or more embodiments of the present technology. As shown in FIG. 7A, the piezoelectric layer 724 of the MIM stack 720a can be an example of the piezo electric layers 222, 322, 422, or 522 illustrated in FIGS. 2-5. This MIM stack 720a comprises a first electrode layer 722, a second electrode layer 726, and a piezoelectric layer 724 therebetween. The first electrode layer 722 and the piezoelectric layer 724 form a first interface 723 therebetween, and the second electrode layer 726 and the piezoelectric layer 724 form a second interface 725 therebetween. A voltage source 750 can be electrically coupled to the first electrode layer 722 and the second electrode layer 726. More specifically, the negative terminal of the voltage source 750 can be electrically coupled to the first electrode layer 722 so that the first electrode layer 722 can act as a cathode, and the positive terminal of the voltage source 750 can be electrically coupled to the second electrode layer 726 so that the second electrode layer 726 can act as an anode.

When an E-field is applied to the piezoelectric layer 724, the induced strain may not be uniformly distributed throughout the piezoelectric material. The formation and migration of these defects can be influenced by the applied electrical field. As illustrated in FIG. 7A, the strain as well as strain caused defect tends to be more pronounced near the surfaces where the E-field is applied, such as close to the anode and cathode surfaces. This could be because the electric field strength is typically higher near the electrode layers 722 and/or 726, leading to greater mechanical deformation in these regions. As a result, the material experiences varying degrees of strain, with the highest levels often observed near the anode surface.

FIG. 7A illustrates an example of forming mechanical strain and defects close to the upper interface 725 of the MIM stack 720a. As shown, near the anode surface, where the electric field is strongest, the likelihood of defect formation is higher. This is due to the increased mechanical stress and strain in this region, which can cause the crystal lattice of the piezoelectric layer 724 to become distorted and more susceptible to defects. In some other embodiments, the configuration of the MIM stack can be adjusted to modify the location of strain and defects in the piezoelectric material. For example, FIG. 7B illustrates another example of forming mechanical strain and defects close to the lower interface 723 of the MIM stack 720b. In this example, the negative terminal of the voltage source 750 can be electrically coupled to the second electrode layer 726 so that the second electrode layer 726 can act as a cathode, and the positive terminal of the voltage source 750 can be electrically coupled to the first electrode layer 722 so that the second electrode layer 726 can act as an anode.

In the present technology, the location of the strain and defects cumulated in the piezoelectric material can be related to the directions of applied E-field. As illustrated in FIGS. 7A, 7B and 8, the strain and defects in a piezoelectric material can be closer to the anode surface/interface. Near the anode, the electric field strength is typically higher due to the proximity to the positive charge. This higher electric field can induce greater mechanical strain in the material. As the distance from the anode increases, the electric field strength decreases, resulting in less strain near the cathode. In addition, piezoelectric materials can be polarized, having a built-in electric dipole moment. When an external electric field is applied, it can interact with the piezoelectric material's polarization. For example, near the anode interface, the alignment of the E-field with the piezoelectric material's polarization can enhance the strain effects. Conversely, near the cathode interface, the interaction may be less pronounced, resulting in reduced strain. In some other embodiments, depending on the properties of the piezoelectric material, the strain and defects resulted from applied E-field can be disposed closer to the cathode surface/interface of the piezoelectric material. In some other examples, the E-field induced strain and defects are disposed close to the anode interface and the cathode interface.

FIG. 8 is an enlarged, partially schematic diagram of a semiconductor device manufacturing system 800 after debonding or delamination, and configured in accordance with embodiments of the present technology. As discussed above with reference to FIGS. 2 to 5, the formation of strain and defects in the piezoelectric layer can facilitate delamination of a device wafer or device die from a carrier wafer. Subsequently, as illustrated in FIG. 8, a carrier wafer 810 is separated from a device wafer 830. Device layers on the device wafer 830 are omitted for illustrative purposes. Here, wafer debonding processes such as mechanical debonding can be adopted to release the device wafer 830 (or individual semiconductor dice as illustrated in FIG. 5) through breaking the interface bonding between an original piezoelectric layer and corresponding electrode. In this example, the delamination can happen along the interface close to the piezoelectric layer 822b and the second electrode layer 824. In some other examples, depending on the configuration of applied bias voltage and piezoelectric layer material properties, the delamination of device wafer 830 can be along an interface between the piezoelectric layer 822a and the first electrode layer 820.

In this example, the first electrode layer 820 and the piezoelectric layer 822a can remain bonded to the carrier wafer 810 after delamination. In embodiments in which a MIM stack structure with multiple piezoelectric layers is used, the second piezoelectric layer can also remain bonded to the carrier wafer 810 after delamination. As shown in FIG. 8, a second electrode layer 824, a bonding layer 826, and a second piezoelectric layer 822b can remain with the device wafer 830. For example, the bonding layer 826 is disposed on a backside surface of the device wafer 830. The bonding layer 826 has a backside surface facing away from the backside surface of the device wafer 830. In addition, the second electrode layer 824 is disposed on the backside surface of the bonding layer 826. Here, the second electrode layer 824 has a backside surface facing away from the backside surface of the bonding layer 826. As shown in FIG. 8, the second piezoelectric layer 822b is disposed on the backside surface of the second electrode layer 824. In some other embodiments, the piezoelectric layer 822b can behave in various physical forms, each with distinct characteristics and implications for its application and handling. For example, the piezoelectric layer 822b can be particulates, e.g., small, discrete particles of the piezoelectric material ranging in size from micro-scale to macro-scale. Further, the piezoelectric layer 822b can be debris, including irregularly shaped piezoelectric material fragments. These debris can be generated as a by-product during the device wafer debonding process, or small pieces of piezoelectric material that accumulate on the backside surface of the device wafer during processing. In addition, the piezoelectric layer 822b can be piezoelectric material fragments such as larger pieces of the piezoelectric material that have broken off from a larger body. During the device wafer debonding process, the piezoelectric layer of the MIM stack might be intentionally broken into fragments. Last but not least, the piezoelectric layer 822b may be in a form of a residual layer, remaining a thin coating or film of piezoelectric material that exists on the backside of the device wafer after the wafer debonding process.

In this example, the carrier wafer 810 can then be cleaned (e.g., have the remaining layers thereon removed) and/or otherwise processed for reuse. As previously mentioned, the use of a MIM stack configured in accordance with embodiments of the present technology eliminates the need to destructively remove the carrier wafer 810 from the device wafer 830. This allows the carrier wafer 810 to be reused for additional device wafers, thus saving material and process costs associated with using and destroying a new carrier wafer for each device wafer to be processed. Here, the second piezoelectric layer 822bm, the second electrode layer 824, and the bonding layer 826 can either remain on the device wafer 830 downstream (e.g., as part of the final semiconductor device) or removed off the device wafer 830. In some cases, a portion of the second electrode layer 824 remaining on the device wafer 830 comprises remnants of the second electrode layer 824 after the electrode removal process.

In some other examples, the carrier wafer 810 may also include another electrode layer on its backside surface after the device wafer debonding process. For example, the device wafer delamination can occur along the interface between the piezoelectric layer 422 and the first electrode layer 420, as described in FIG. 4. Here, the first electrode material including electrode particulates, debris, fragments, or residual electrode layers can be disposed under the piezoelectric layer and on the backside surface of the device wafer.

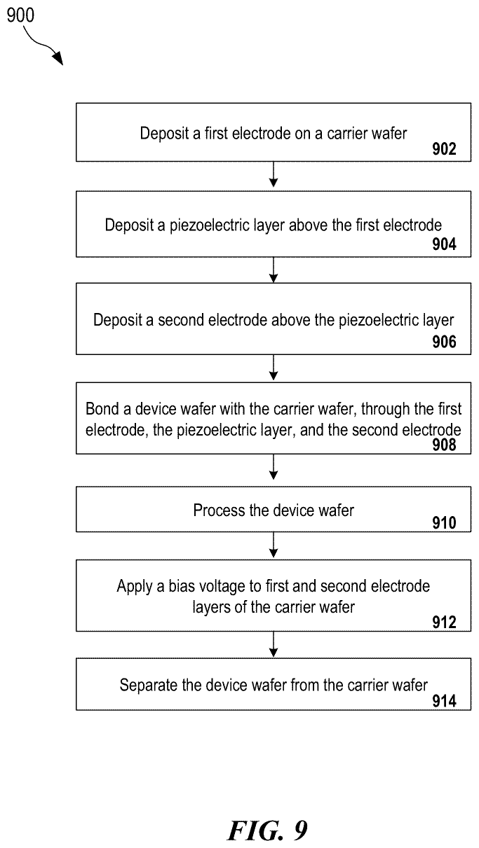

FIG. 9 is a flowchart illustrating a method 900 for manufacturing a semiconductor device in accordance with one or more embodiments of the present technology. For example, the method 900 includes depositing a first electrode layer on a carrier wafer, at 902. For example, the first electrode layer 220 can be deposited on the carrier wafer 210. As shown in FIG. 2, the first electrode layer 220 can surround the frontside surface, edge surfaces, and backside surface of the carrier wafer 210.

The method 900 also includes depositing a piezoelectric layer above the first electrode, at 904. For example, the piezoelectric layer 222 can be deposited on the first electrode layer 220, as shown in FIG. 2. In some other examples, the piezoelectric layer 322 can be deposited on the first electrode layer 320, above the frontside surface of the carrier wafer 310, as shown in FIG. 3.

The method 900 further includes depositing a second electrode layer above the piezoelectric layer, at 906. For example, the second electrode layer 224 can be deposited on the piezoelectric layer 222, as shown in FIG. 2. In some other examples, the second electrode layer 324 can be deposited on the piezoelectric layer 322, above the frontside surface of the carrier wafer 310, as shown in FIG. 3. The deposition of the first electrode, piezoelectric layer, and second electrode completes fabrication of the MIM stack structure of the present technology.

In addition, the method 900 includes bonding a device wafer to the carrier wafer, through the first electrode layer, the piezoelectric layer, and the second electrode layer, at 908. For example, the device wafer 230 can be bonded, through the bonding layer 226 and using proper semiconductor bonding technologies, on the MIM stack 260 of the carrier wafer 210, as shown in FIG. 2. In some other examples, semiconductor device dice such as device dice 530a, 530b, and 530c can be bonded on the MIM stack 560 of the carrier wafer 510, as shown in FIG. 5.

The method 900 also includes processing the device wafer, at 910. For example, various semiconductor device fabrication processes can be conducted on the device wafer 230 to create integrated circuits thereon. Here, the semiconductor device fabrication processes may include wafer preparation, oxidation, photolithography, etching, doping, deposition, chemical mechanical planarization, metallization, passivation, and testing and packaging processes.

Moreover, the method 900 includes apply a bias voltage to the first and second electrode layers of the carrier wafer to generate strain in the piezoelectric layer, at 912. For example, a bias voltage can be generated from the voltage source 250 and applied on the first and second electrode layers 220 and 224. As described in FIGS. 2, 7A and 7B, the bias voltage generates strain in the piezoelectric layer 222.

Lastly, the method 900 includes separating the device wafer from the carrier wafer, at 914. For example, the device wafer 830 can be separated from the carrier wafer 810 using a semiconductor wafer debonding processes such as mechanical debonding. In this example, the delamination may happen along the interface between the piezoelectric layer and the second (upper) electrode of the MIM stack structure. As shown in FIG. 8, after the debonding process, piezoelectric residual layer 822b, the second electrode layer 824, as well as the bonding layer 826 may exist on the backside surface of the device wafer 830.

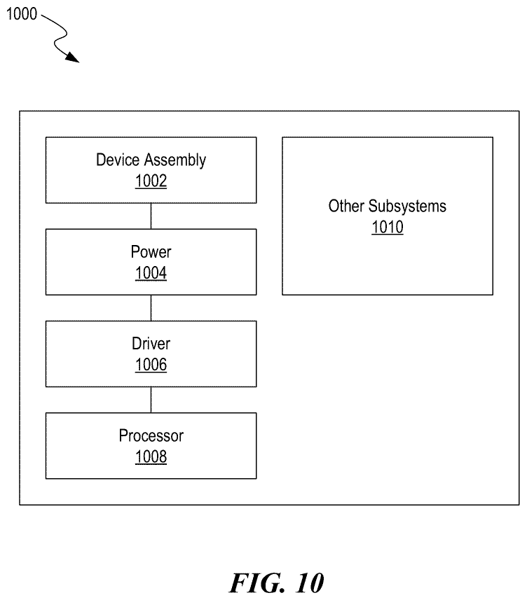

Any one of the semiconductor device assembly technology described above with reference to FIGS. 1 to 8 can be incorporated into any of a myriad of larger and/or more complex systems, a representative example of which is system 1000 shown schematically in FIG. 10. The system 1000 can include a semiconductor device assembly (e.g., or a discrete semiconductor device) 1002, a power source 1004, a driver 1006, a processor 1008, and/or other subsystems or components 1010. The semiconductor device assembly 1002 can include features generally similar to those of the semiconductor wafer assembly, specifically the MIM stack structure on a carrier wafer incorporating piezoelectric layer and electrodes, described above with reference to FIGS. 2 to 5. The resulting system 1000 can perform any of a wide variety of functions, such as memory storage, data processing, and/or other suitable functions. Accordingly, representative systems 1000 can include, without limitation, hand-held devices (e.g., mobile phones, tablets, digital readers, and digital audio players), computers, vehicles, appliances and other products. Components of the system 1000 may be housed in a single unit or distributed over multiple, interconnected units (e.g., through a communications network). The components of the system 1000 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor wafer, comprising:
a bonding layer disposed on a backside surface of the semiconductor wafer, the bonding layer having a backside surface facing away from the backside surface of the semiconductor wafer;
a first electrode layer disposed on the backside surface of the bonding layer, the first electrode layer having a backside surface facing away from the backside surface of the bonding layer; and
piezoelectric material disposed on the backside surface of the first electrode layer.

2. The semiconductor wafer of claim 1, wherein the piezoelectric material is disposed in particulates, debris, fragments, or residual layers.

3. The semiconductor wafer of claim 1, wherein the piezoelectric material includes electric field induced strain.

4. The semiconductor wafer of claim 1, wherein the piezoelectric material is made of Lead Zirconate Titanate (Pb(Zr,Ti)O₃), Lead Zinc Niobate (Pb(Zn,Nb)O₃), Lead Titanate (PbTiO₃), Barium Titanate (BaTiO₃), or a combination thereof.

5. The semiconductor wafer of claim 1, wherein the piezoelectric material includes dislocations or microcracks.

6. The semiconductor wafer of claim 1, wherein the piezoelectric material includes point defects caused by reversible domain switching.

7. The semiconductor wafer of claim 1, wherein the semiconductor wafer comprises one or more memory devices or one or more Complementary Metal-Oxide-Semiconductor (CMOS) devices, and wherein the one or more memory devices comprises dynamic random access memory (DRAM) devices or NAND flash memory devices.

8. The semiconductor wafer of claim 1, wherein the piezoelectric material is disposed in a continuous piezoelectric layer, and wherein the piezoelectric layer has a thickness ranging from 1 nm to 1 μm.

9. The semiconductor wafer of claim 8, further comprising a second electrode material disposed under the piezoelectric layer.

10. The semiconductor wafer of claim 9, wherein the second electrode material is disposed in particulates, debris, fragments, or residual layers.

11. A semiconductor device manufacturing system, comprising:
a carrier wafer;
a first electrode layer disposed on the carrier wafer;
a piezoelectric layer disposed on the first electrode layer;
a second electrode layer disposed on the piezoelectric layer;
a device wafer having a bonding layer disposed on a surface of the device wafer; and
a power source having a first terminal and a second terminal,
wherein the device wafer is bonded to the carrier wafer through the bonding layer, the first electrode layer, the piezoelectric layer, and the second electrode layer,
wherein the second electrode layer is configured to separate from the first electrode layer upon application of a bias voltage to the first and second electrode layers, and
wherein the device wafer is configured to debond from the carrier wafer through delaminating the piezoelectric layer from the first electrode layer or the second electrode layer.

12. The semiconductor device manufacturing system of claim 11, wherein the first electrode layer wraps around a frontside surface and a backside surface of the carrier wafer, wherein the piezoelectric layer and the second electrode layer are disposed on the frontside surface of the carrier wafer and partially disposed on the backside surface of the carrier wafer, exposing a portion of the first electrode layer, and wherein the first terminal of the power source is connected to the portion of the first electrode layer and the second terminal of the power source is connected to the second electrode layer.

13. The semiconductor device manufacturing system of claim 11, wherein the first electrode layer wraps around a frontside surface and a backside surface of the carrier wafer, wherein the piezoelectric layer and the second electrode layer are disposed on the frontside surface of the carrier wafer, wherein the device wafer is edge trimmed and the second electrode layer is exposed on edge of the frontside surface of the carrier wafer, and wherein the second terminal of the power source is connected to exposed portion of the first electrode layer above the frontside surface of the carrier wafer and the first terminal of the power source is connected to the first electrode layer.

14. The semiconductor device manufacturing system of claim 11, further comprising a first through silicon via (TSV) and a second TSV that are embedded in the carrier wafer, the first and second TSVs extending from a backside surface to a frontside surface of the carrier wafer, wherein the first electrode layer, the piezoelectric layer, and the second electrode layer are sequentially disposed on the frontside surface of the carrier wafer, wherein the first terminal of the power source is connected to the first electrode layer through the first TSV, and wherein the second terminal of the power source is connected to the second electrode layer through the second TSV.

15. A method comprising:
depositing a first electrode layer on a carrier wafer;
depositing a piezoelectric layer above the first electrode layer;
depositing a second electrode layer above the piezoelectric layer;
bonding a device wafer to the carrier wafer, through the first electrode layer, the piezoelectric layer, and the second electrode layer;
processing the device wafer;
applying a bias voltage to the first and second electrode layers of the carrier wafer to generate strain in the piezoelectric layer; and
separating the device wafer from the carrier wafer.

16. The method of claim 15, wherein applying the bias voltage comprises degrading a first portion of the piezoelectric layer at a first interface between the first electrode layer and the piezoelectric layer.

17. The method of claim 16, wherein applying the bias voltage further comprises degrading a second portion of the piezoelectric layer at a second interface between the second electrode layer and the piezoelectric layer.

18. The method of claim 17, wherein separating the device wafer from the carrier wafer comprises delaminating the device wafer from the carrier wafer along the first portion of the piezoelectric layer, the second portion of the piezoelectric layer, or a combination thereof.

19. The method of claim 15, wherein processing the device wafer comprising fabricating one or more memory devices or one or more Complementary Metal-Oxide-Semiconductor (CMOS) devices, and wherein the one or more memory devices comprises dynamic random access memory (DRAM) devices or NAND flash memory devices.

20. The method of claim 15, further comprising cleaning residue piezoelectric layer from the device wafer and the carrier wafer.
